(19) United States
(12) Patent Application Publication
(10) Pub. No.: US 2026/0282204 A1
(43) Pub. Date: Sep. 17, 2026

(54) CIRCUIT BOARD STIFFENER AND COLD PLATE

(71) Applicant: MELLANOX TECHNOLOGIES, LTD., Yokneam (IL)

(72) Inventors: Dima Denisenko, Afula (IL); Alex Kremenetsky, Kiriat Bialik (IL); Shalom Alexander Gurevich, Karmiel (IL); Moti Cabessa, Ramat-Gan (IL); Michael Dolinski, Kiryat Ata (IL)

(21) Appl. No.: 19/080,897

(22) Filed: Mar. 16, 2025

(51) Int. Cl. H05K 1/02

(52) U.S. Cl. CPC H05K 1/0203; H05K 2201/04; H05K 2201/064; H05K 2201/066; H05K 2201/10151; H05K 2201/10409

(57) ABSTRACT

This disclosure is directed to a stiff cold plate for dissipating heat from one or more heat-generating components, such as those associated with a PCB. The stiff cold plate connects to the PCB through various connecting elements, including screws, fasteners, or other suitable components. Once attached, the stiff cold plate helps prevent warpage of the PCB by providing additional stiffness. The stiff cold plate also dissipates heat generated by the PCB and its associated elements, such as CPUs, through an integrated cooling loop.

### BACKGROUND

PCBs frequently encounter warpage and overheating during operation, which may lead to significant performance degradation and potential failure of the electronic components on the PCB. Once overheating occurs, it is challenging to rectify the situation, often resulting in costly downtime and repairs. Preventing these issues may involve implementing multiple separate components or systems, which may be inefficient and consume valuable space within the system. This inefficiency not only complicates the design process but also increases manufacturing costs and limits the overall compactness of electronic devices on the PCB.

### BRIEF DESCRIPTION OF THE DRAWINGS

Various embodiments in accordance with the present disclosure will be described with reference to the drawings, in which:

FIG. 1A illustrates a stiff cold plate according to example embodiments;

FIG. 1B illustrates a system for dissipating heat from a PCB via a stiff cold plate according to example embodiments;

FIG. 2A illustrates a PCB and a stiff cold plate according to example embodiments;

FIG. 2B illustrates a cross-sectional view of a PCB and stiff a cold plate according to example embodiments;

FIG. 2C illustrates a cross-section view of a PCB and a stiff cold plate with connecting elements according to example embodiments;

FIG. 2D illustrates a cross-section view of a PCB, a stiff cold plate, and an insulating layer according to example embodiments;

FIG. 3A illustrates a stiff cold plate and a PCB according to example embodiments;

FIG. 3B illustrates a stiff cold plate to connect with multiple PCBs according to example embodiments;

FIG. 3C illustrates a stiff cold plate with temperature sensors according to example embodiments;

FIGS. 4A, 4B, and 4C illustrate stiff cold plates with various cooling loops according to example embodiments;

FIG. 5A illustrates a process for dissipating heat from a PCB via a stiff cold plate;

FIG. 5B illustrates a process for transmitting temperature information from a stiff cold plate to a controller according to example embodiments;

FIG. 6 illustrates components of a distributed system that may be utilized in a data center, according to at least one embodiment;

FIG. 7 illustrates an example data center system, according to at least one embodiment;

FIG. 8 illustrates an example computing environment, according to at least one embodiment;

FIG. 9 illustrates a computer system, according to at least one embodiment;

FIG. 10 illustrates a computing system, according to one or more embodiments;

FIG. 11 illustrates an optoelectronic component according to example embodiments;

FIG. 12 illustrates an optoelectronic component according to example embodiments;

FIG. 13 illustrates an optoelectronic component with a substrate and integrated circuit according to example embodiments;

FIG. 14 illustrates an optoelectronic component in a transceiver according to example embodiments; and

FIG. 15 illustrates a networking device according to example embodiments.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

In some environments, soldering joints are at risk of cracking or breaking due to deformation of the PCB. Some mechanical stiffeners may be employed to mitigate this risk by transferring stress from the soldering joints to the stiffener. For example, a separate stiffener may be utilized to alleviate stress on the solder joints. To provide both a stiffening force and a heat-dissipating effect, a stiff cold plate may be integrated into the main PCB as part of a liquid cooling system, rather than as a separate component. An integrated liquid cooling system may utilize a portion of the mechanical stiffener for cooling the PCB. The combination of stiffener with a cold plate creates additional space for a denser area, enhancing tolerance variations in the cooling environment and improving cooling of the PCB by utilizing the stiffener as a cold plate.

This disclosure is directed to a stiff cold plate for dissipating heat from one or more heat-generating components such as those associated with a PCB. The stiff cooling plate may be a generally flat plate of a broadly similar shape to the PCB. The cooling plate can mate with the PCB and circulate cooling fluids via an internal cooling loop. The stiff cold plate serves a dual purpose: it acts as both a stiffener for the PCB and a liquid cooling feature. This integration helps in mounting other components and improves the thermal management of the system.

The stiff cold plate may connect to the PCB through one or more connecting elements such as screws, fasteners, bolts or other suitable elements. Once attached to the PCB, the stiff cold plate may prevent warpage of the PCB by stiffening the PCB against physical twisting, bending, or other physical force. This stiffening force also protects the one or more soldering joints on the PCB from breaking, cracking, or suffering any damage due to other physical forces. The stiff cold plate may also dissipate heat-generating by the PCB and its associated elements (e.g., CPUs) by a cooling loop integrated into the stiff cold plate and proximate to one or more heat-generating components on the PCB. The stiff cold plate may include an inlet element and an outlet element to receive and discharge cooling fluid and circulate the cooling fluid proximate to heat-generating components on the PCB through the cooling loop. The cooling loop integrated into the stiff cold plate may circulate proximate one or more portions of the PCB, and in some embodiments, the cooling loop may run proximate to the heat-generating components on the PCB. In some example embodiments, the stiff cold plate may removably attach to one PCB, and in other embodiments, the stiff cold plate may be large enough to removably attach with multiple PCBs, multiple CPUs, or indeed multiple of any heat-generating element.

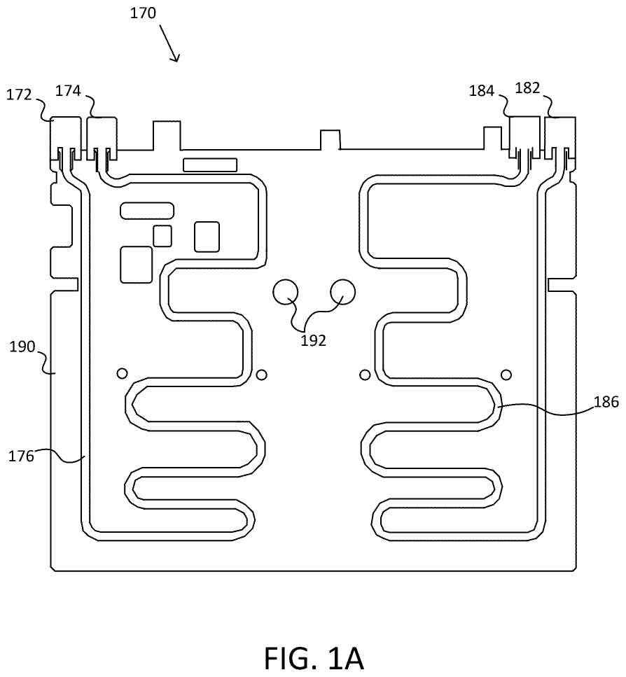

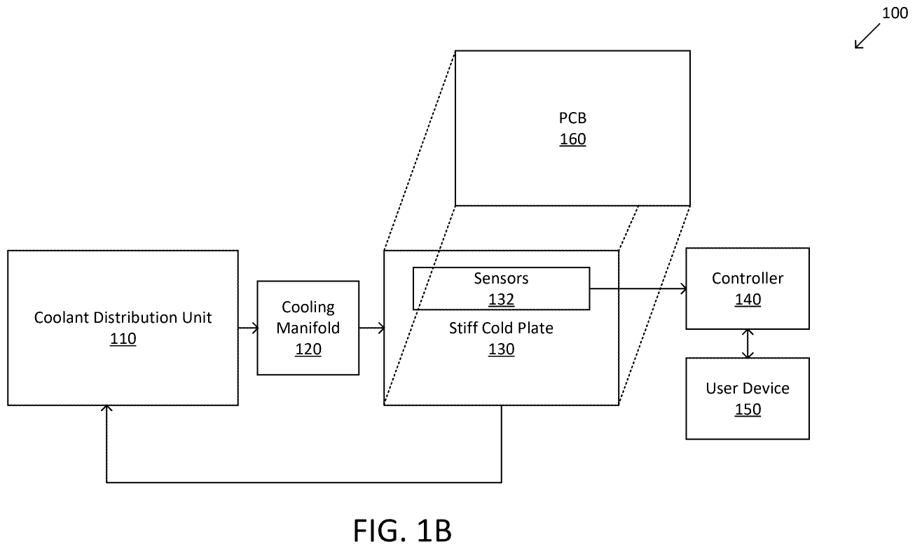

In FIG. 1A, a stiff cold plate 170 may include a body 190 and a first cooling loop 176 and a second cooling loop 186. The cold plate 170 may be removably attached to a PCB (not illustrated) to dissipate heat from one or more heat-generating components on the PCB. The body 190 of the stiff cold plate 170 may include a first side and a second side, such as a top side and a bottom side. The first cooling loop 176 and the second cooling loop 186 may be removably attached to either or both the bottom side or top side of the body 190 of the stiff cold plate 170. An inlet element 172 may circulate cooling fluid through the first cooling loop 176, and an outlet element 174 may discharge the cooling fluid into, without limitation, a manifold, a tubing, or a CDU. Similarly, an inlet element 182 may circulate fluid through a second cooling loop 186, and an outlet element 184 may discharge the cooling fluid into, without limitation, a manifold, a tubing, or a CDU. In other example embodiments, inlet elements 172 and 182 as well as the outlet elements 174 and 184 may be located at other points on the stiff cold plate 170. For example, the inlet elements 172 and 182 as well as the outlet elements 174 and 184 may be placed on opposite ends of the stiff cold plate 170, or the inlet elements 172 and 182 may be placed at different locations relative to the outlet elements 174 and 184. The stiff cold plate 170 may also include one or more connecting holes 192 which may align with one or more corresponding connecting holes on a PCB (not illustrated). In example embodiments, one or more connecting elements such as screws, bolts, or fasteners may be threaded through the connecting holes 192. Although FIG. 1A illustrates the stiff cold plate 406 with a particular shape and one or more dimensions, in other example embodiments, the stiff cold plate 170 may be shaped in other suitable dimensions such as circular, rectangular, triangular, or any other suitable shape to connect to one or more PCBs. Furthermore, the first cooling loop 176 and the second cooling loop 186 are illustrated as snaking or zig-zagging one or more times across one or more portions of the body 190 of the stiff cold plate 170. In other example embodiments, the first cooling loop 176 and the second cooling loop 186 may cover different portions of the body 190 of the stiff cold plate 170. Furthermore, a greater or fewer number of cooling loops may be integrated into other cold plates not illustrated herein.

FIG. 1B illustrates a cooling assembly 100 for dissipating heat from one or more heat-generating components through a stiff cold plate 130. The cooling assembly 100 may correspond to one or more data centers or other similar environments where heat-generating components are being used. The cooling assembly 100 may include without limitation a coolant distribution unit (CDU) 110, a cooling manifold 120 including one or more cooling loops, a stiff cold plate 130, a controller 140, a user device 150, and a PCB 160.

The CDU 110 may distribute cooling fluid through a cooling manifold 120 to the stiff cold plate 130. The stiff cold plate 130 may connect to or be proximate to one or more heat-generating components on the PCB 160. The stiff cold plate 130 may include one or more temperature sensors 132 including temperature sensors to determine temperature information of one or more heat-generating components on or corresponding to the PCB 160 proximate to or near the stiff cold plate 130. The stiff cold plate 130 and the temperature sensors 132 may be connected through a wired or wireless connection to the controller 140. Through this connection, the temperature sensors 132 may transmit one or more temperature information to the controller 140. The controller 140 may transmit this information to a user device 150 including a computer-enabled device, administrator device, or any device associated with a user. The user device 150 may interface with the controller 140 to observe temperature information and other information associated with the cooling assembly 100. The user device 150 and controller 140 may both include or either include a processor (e.g., a central processing unit (CPU) or graphics processing unit (GPU)), data processing units (DPUs), quantum processing units (QPUs), a plurality of parallel processing units (PPUs), and application-specific integrated circuits (ASICs) memory module, or power supply. QPUs configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

Generally, the CDU 110 may include an apparatus designed to circulate cooling fluid such as water or a water-glycol mixture through the cooling manifold 120. By circulating the cooling fluid, the CDU 110 may manage the temperature of heat-generating elements, such as the PCB 160, servers, or other hardware. The CDU 110 may circulate the cooling fluid to absorb or dissipate heat from these heat-generating elements, thereby stabilizing temperatures and preventing overheating of the heat-generating elements. In some example embodiments, the CDU 110 may operate using a refrigeration cycle, which involves a compressor, which compresses refrigerant gas, allowing it to absorb heat from the water, thus cooling the fluid before it is circulated back to the stiff cold plate 130. Additionally, the CDU 110 may include control systems which monitor the temperature of the cooling fluid and adjust the cooling output as needed to maintain desired temperature levels.

The cooling manifold 120 may include a manifold system designed to facilitate the distribution and routing of cooling fluid from the CDU 110 to various components within the cooling assembly 100 including the stiff cold plate 130. The cooling manifold 120 may be a central hub which connects cooling loops leading to the stiff cold plate 130, allowing for efficient fluid flow and temperature regulation across different areas of the cooling assembly 100. Although FIG. 1B illustrates the cooling manifold 120 connecting to only one stiff cold plate 130, it is understood that in other example embodiments the cooling manifold 120 may connect to multiple cold plates or indeed other cooling or heat-generating elements in the cooling assembly 100. In example embodiments, the cooling manifold 120 may be constructed from materials such as durable plastics, aluminum, or stainless steel, which provide resistance to corrosion and may withstand varying pressures and temperatures.

In some embodiments, a stainless steel adapter is used to avoid direct contact between stainless steel and copper to avoid galvanic corrosion when connecting stainless steel to copper. A stainless steel adapter may be with O-rings and a coating for the touching area, preventing corrosion in the liquid environment.

The stiff cold plate 130 may include, without limitation, a layer or sheet of metal to connect to one or more or other heat-generating components. In some example embodiments, the stiff cold plate 130 may be constructed from materials such as aluminum (e.g., aluminum die casting), steel, copper, or other metals or compositions. These materials may provide rigidity to prevent warping of the PCB 160 while effectively dissipating heat generated by associated heat-generating components. The shape of the stiff cold plate 130 may vary, with some example embodiments including rectangular plates, circular forms, or custom shapes designed to fit specific layouts of the PCB 160 or other heat-generating elements. The design may be tailored to maximize surface area for heat transfer while ensuring compatibility with the overall architecture of the PCB 160 and heat-generating elements. Additionally, the stiff cold plate 130 may incorporate an insulation layer made from suitable materials such as foam or fiberglass which is placed between the metal layer of the stiff cold plate 130 and the PCB 160. This insulation layer may minimize electrical interference between the stiff cold plate 130 and the PCB 160 and ensure proper grounding. This separation ensures that the grounding of the unit does not mix with the signals from the unit, avoiding electrical interference and potential failures.

The stiff cold plate 130 may include an inlet element and an outlet element. The stiff cold plate 130 may receive cooling fluid from the cooling manifold 120 through the inlet element, circulate the cooling fluid through a cooling loop throughout the stiff cold plate 130, and discharge the cooling fluid through the outlet element. The cooling loop may be integrated into the stiff cold plate 130 itself or be removably attached to the stiff cold plate 130. The cooling loop may dissipate heat from the one or more heat-generating components before discharging the cooling fluid through the outlet element. In some embodiments, the cooling fluid may be discharged back into the CDU 110. Cooling fluid may be circulated to the stiff cold plate 130 continuously or in response to one or more temperature readings gathered by the temperature sensors 132.

The stiff cold plate 130 may include one or more temperature sensors 132 which may generate temperature information regarding the temperature of the PCB 160 or other heat-generating elements. These temperature sensors 132 may monitor the thermal conditions in real-time and provide temperature information which may be used by the controller 140 and user device 150 to improve cooling performance of the cooling assembly 100. In example embodiments, the temperature sensors 132 may generate temperature information and transmit it to the controller 140 and/or a user device 150, which may then utilize this temperature data to adjust the cooling liquid flow in the cooling loop or make determinations about the overall cooling strategy for the cooling assembly 100. The temperature sensors 132 may include thermocouples or thermistors, which may measure the electrical resistance or voltage changes which occur in response to temperature variations. The temperature sensors 132 may gather temperature information by being placed in direct contact with the surface of the stiff cold plate 130 or in proximity to the PCB 160, allowing the temperature sensors 132 to accurately detect heat levels.

The PCB 160 may serve as a housing or base for heat-generating elements such as processors, CPUs, power supplies, and other electronic circuits. The PCB 160 might overheat due to excessive heat generated by the internal components, inadequate cooling solutions, or poor airflow within the enclosure. Furthermore, the PCB 160 may experience warping due to mishandling or overheating. Preventing warpage in the PCB 160 is desirable because warping may compromise the structural integrity of the housing, leading to misalignment of components, potential damage, and reduced performance. The PCB 160 may be made from materials such as aluminum, steel, or high-temperature plastics, which provide durability and thermal conductivity. Connecting the PCB 160 with a stiff cold plate 130 may help manage warping by providing structural support, ensuring that the enclosure maintains its shape under thermal stress.

Additionally, the stiff cold plate 130 aids in heat dissipation via the cooling loop. The stiff cold plate 130 may be connected with the PCB 160 via one or more connecting elements including without limitation screws, fasteners, or other suitable connecting elements. In example embodiments, one stiff cold plate 130 may be removably attached to one PCB 160, and in other example embodiments, one stiff cold plate 130 may be large enough to removably attach to multiple PCBs 160.

The controller 140 may include one or more components of one or more devices, systems, and/or the like, referred to as modules, which carry out (i.e., perform, execute, and the like) various functions. As used in the present disclosure, a module includes both hardware and instructions. The hardware may include one or more processors, one or more microprocessors, one or more microcontrollers, one or more microchips, one or more application-specific integrated circuits (ASICs), one or more field programmable gate arrays (FPGAs), one or more graphical processing units (GPUs), one or more tensor processing units (TPUs), and/or one or more devices and/or components of any other type deemed suitable by those of skill in the art for a given implementation. In some cases, a module includes at least one functional component (e.g., an application or part of an application, a block of code, and/or the like) executing in whole or in part on one or more processors of a host system or device.

The instructions for a given module are executable by the hardware for carrying out the one or more herein-described functions of the module, and may include hardware (e.g., hardwired) instructions, firmware, software, and/or the like, stored in any one or more non-transitory computer-readable media deemed suitable by those of skill in the art for a given implementation. Each such computer-readable medium may be or include memory (e.g., random access memory (RAM), read-only memory (ROM), erasable programmable read-only memory (EPROM), electrically erasable programmable read-only memory (EEPROM a.k.a. EPROM), flash memory, and/or one or more other types of memory) and/or one or more other types of non-transitory computer-readable medium. A module may be realized as a single component or be distributed across multiple components as deemed suitable by those of skill in the art.

The user device 150 may include one or more computer-enabled devices, such as those including one or more input devices and one or more output devices. With respect to input devices, the user device 150 include one or more touchscreens, keyboards, mice, trackpads, touchpads, other pointing devices, buttons, switches, knobs, microphones, and/or the like. With respect to output devices, the user device 150 may include one or more displays (e.g., the display), monitors, speakers, light-emitting diodes (LEDs), and/or the like.

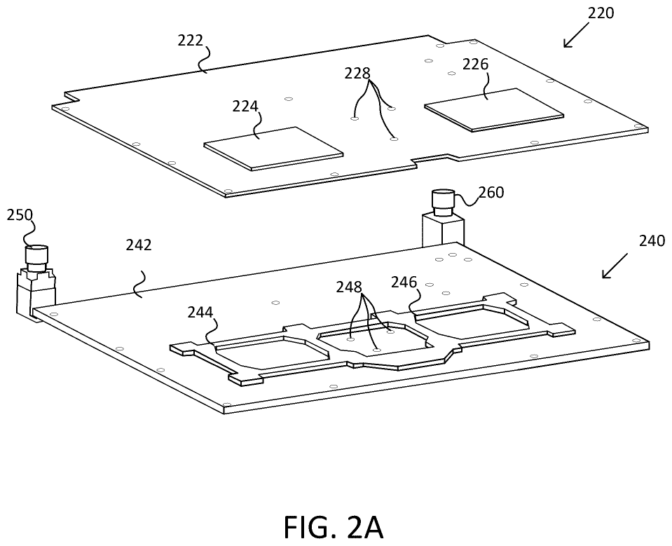

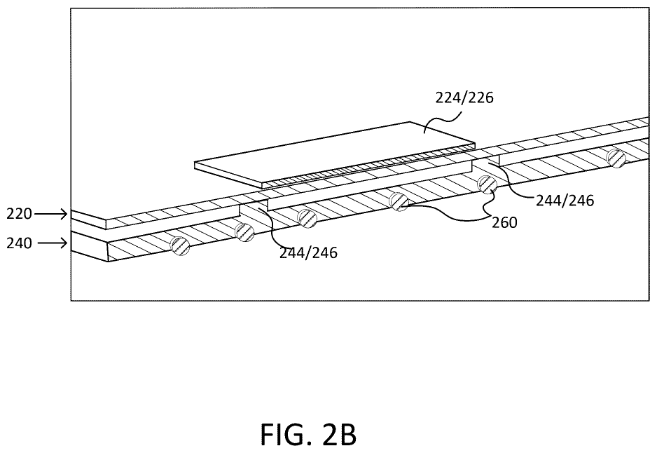

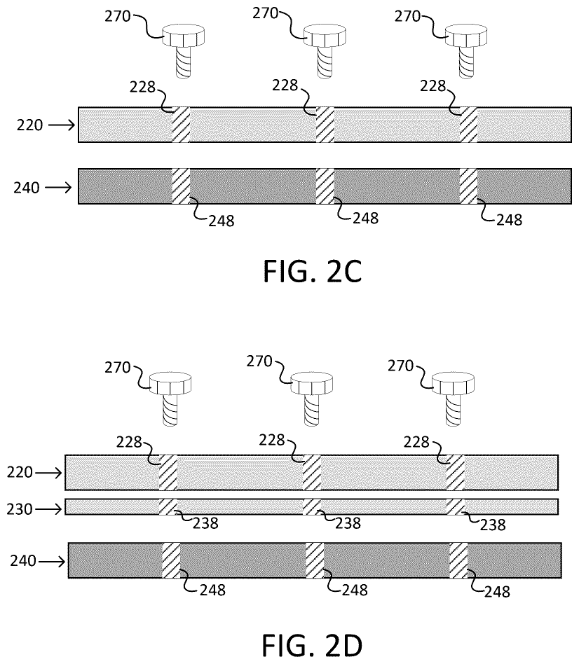

FIG. 2A illustrates a PCB 220 and a stiff cold plate 240. The stiff cold plate 240 may connect to the PCB 220 and act as both a stiffener to prevent warpage and a heat-dissipator from one or more heat-generating components on the PCB 220.

The PCB 220 may include a first side 222 on which one or more heat-generating components 224 and 226 may be placed. In example embodiments, the heat-generating components 224 and 226 may include CPUs or other such similar heat-generating components. The PCB 220 it also includes one or more connecting holes 228 through which one or more connecting elements may be threaded to connect the PCB 220 to the stiff cold plate 240. The stiff cold plate 240 may include a first side 242 on which there are one or more thermal elements 244 and 246 corresponding to the heat-generating components 224 and 226 from the PCB 220. The thermal elements 244 and 246 may include thermal pads to place the stiff cold plate 240 in thermal contact with the PCB 220. Furthermore, the stiff cold plate 240 may include one or more connecting holes 248 to be connected to the corresponding connecting holes 228 from the PCB 220. The stiff cold plate 240 may include an inlet element 250 and an outlet element 260.

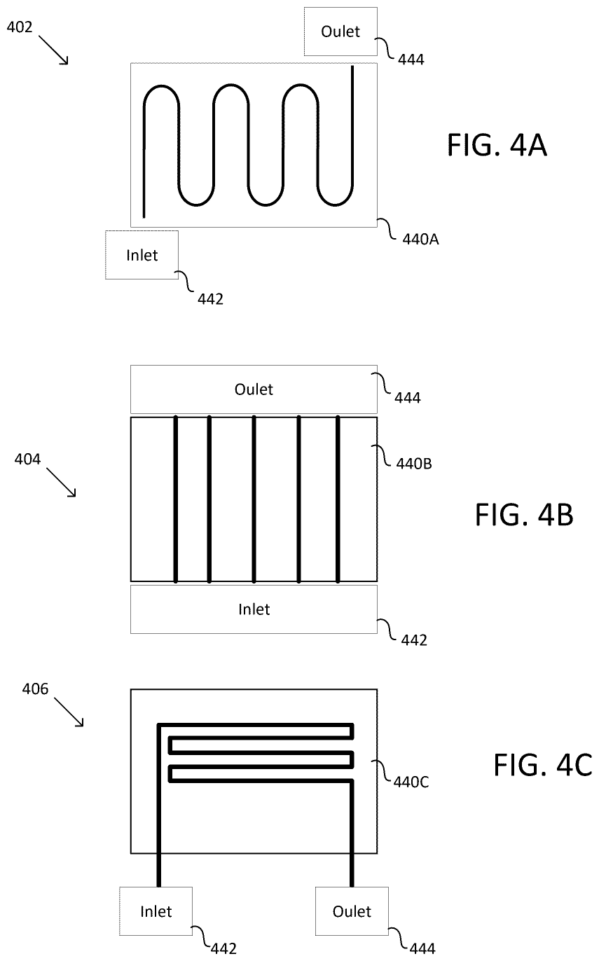

In some embodiments, the inlet element 250 and outlet element 260 may facilitate the flow of cooling fluid to and from the CDU. The inlet element 250 connects to a tube from a cooling manifold and intakes cooling fluid from a CDU, allowing for the efficient transfer of cooling fluid into the stiff cold plate 240. This inlet element 250 may feature a quick disconnect mechanism, enabling rapid connection or removal of the tubing, which is particularly useful for maintenance or system reconfiguration. The outlet elements may receive the cooling fluid after it has circulated through the stiff cold plate 240, having absorbed heat from the heat-generating elements associated with the PCB 220. This element ensures that the warmed fluid is directed back to the CDU for re-cooling. In example embodiments, the inlet element 250 and outlet element 260 may include flexible tubing connectors or quick-release couplings which allow for easy access, while outlet elements could consist of standard pipe fittings or valves which control the flow of the heated fluid. Although not illustrated in FIG. 2A, the stiff cold plate 240 may have a cooling loop running on the other side of the stiff cold plate 240 as described with further reference to FIGS. 2B and 4A-4C.

In some example embodiments, the stiff cold plate 240 may be of the same general shape as the PCB 220. As a nonlimiting example, the PCB 220 may be of a generally rectangular shape, and the stiff cold plate 240 may also be of a generally rectangular shape. In other example embodiments not illustrated herein, the stiff cold plate 240 may be of any shape suitable for dissipating heat from one or more heat-generating components with or without a PCB 220. In other embodiments described herein, the stiff cold plate 240 may be of various sizes, including large enough to removably attach with multiple PCBs or other heat-generating components. The configuration of the stiff cold plate is flexible in size and shape such that the stiff cold plate may be adjusted to surround multiple components and provide adequate thermal management. The shape of the stiff cold plate can be adjusted to surround different components such as multiple silicon chips, ensuring that each component receives adequate stiffening and thermal management, Although FIG. 2A illustrates only a limited number of connecting holes, it is understood that in other embodiments the stiff cold plate 240 and the PCB 220 may include a greater or fewer number of connecting holes. Stiff cold plate 240 and PCB 220 may be connected by one or more connecting elements to be threaded through the connecting holes 22 and 248 such as bolts, screws, fasteners, or any other suitable connecting element. In some embodiments, the stiff cold plate 240 may snap on to the PCB 220 by one or more buttons or straps. The stiff cold plate 240 may be disconnected or removed from the PCB 220 by disconnecting the connecting elements.

The PCB 220 may be connected to the stiff cold plate 240 through various connecting elements, ensuring a secure and effective thermal interface enhancing the overall thermal performance. For instance, the PCB 220 may be attached to the stiff cold plate 240 using screws, bolts, or fasteners, which provide a robust mechanical connection. Additionally, adhesive compounds or thermal interface materials may be employed to enhance thermal conductivity between the PCB 220 and stiff cold plate 240. The positioning of these connecting elements may vary. In some embodiments, they may be located at the corners of both the PCB 220 and stiff cold plate 240, along each of the four sides of the PCB 220 and stiff cold plate 240, near heat-generating elements, or even in the center of either component. In the illustrated example, connecting holes are present on at least three sides of the PCB 220 and the stiff cold plate 240, with some holes offset from the edges, accommodating various configurations and ensuring that the connection may be tailored to meet the needs of different embodiments.

FIG. 2B illustrates a cross-sectional view of the PCB 220 and stiff cold plate 240 when they are connected together. PCB 220 may include one or more heat-generating components 224 and 226. The stiff cold plate 240 may include one or more cooling loops with outlet elements 260 to transport cooling fluid through the stiff cold plate 240 and proximate to the one or more heat-generating components 224 and 226. In some embodiments, the stiff cold plate 240 may comprise one or more thermal elements 244 and 246 (e.g., thermal pads) proximate to the heat-generating components 224 and 226 so that they may be dissipated from the thermal elements 244 and 246.

FIGS. 2C and 2D illustrate perspective cross-sectional views of the PCB 220 and the stiff cold plate 240. As discussed elsewhere herein, the PCB 220 may include one or more connecting holes 228 corresponding to one or more connecting holes 248 in the stiff cold plate 240. One or more connecting elements 270 may be threaded through the connecting holes 228 and 248 to removably attach the PCB 220 to the stiff cold plate 240. The connecting elements 270 may include, without limitation, threaded screws, although in other embodiments it is understood that other connecting elements may be made such as fasteners or any other suitable connecting element. In FIG. 2D, an insulating layer 230 may be located in between the stiff cold plate 240 and the PCB 220. The insulating layer 230 may itself include one or more connecting holes 238 to line up with the connecting holes 228 and 248 from the PCB 220 and stiff cold plate 240. The insulating layer 230 may prevent any electrical interference from the stiff cold plate 240 in the functioning of the computing components on the PCB 220. The size of the PCB 220, stiff cold plate 240, and insulating layer 230 may have been exaggerated in FIGS. 2C and 2D for the purpose of illustrating the elements, and it is understood that the exact length and the thickness of the stiff cold plate 240, PCB 220, and insulating layer 230 may vary from what is illustrated in FIGS. 2C and 2D.

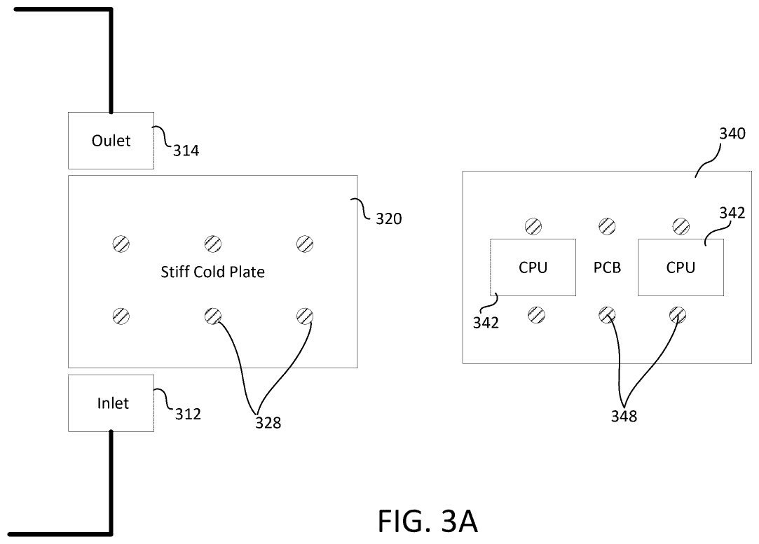

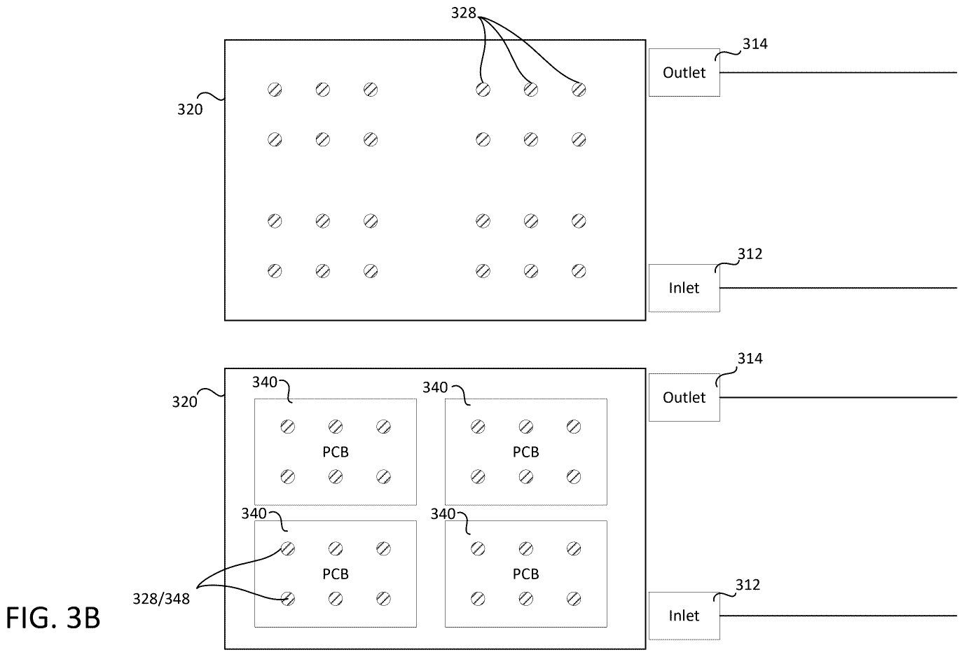

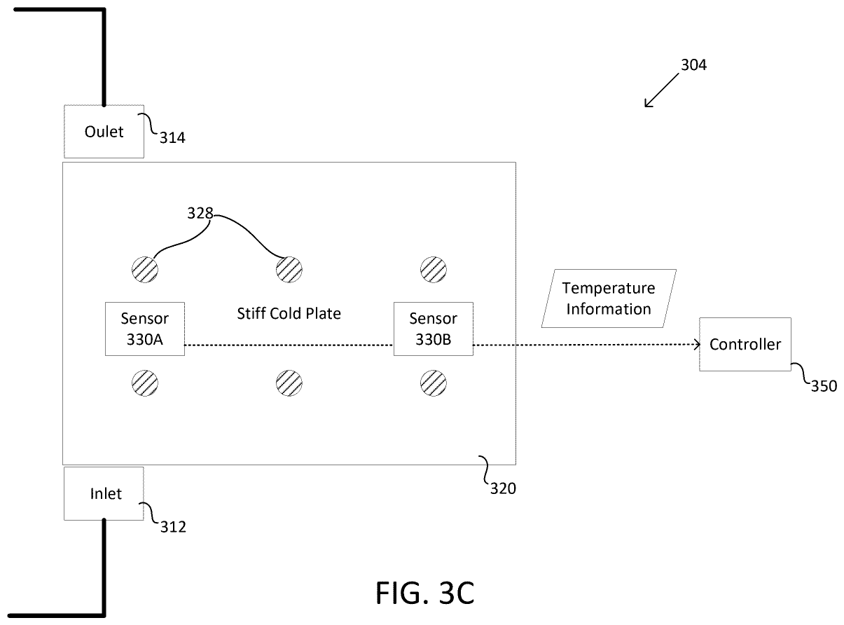

FIG. 3A is a diagram illustrating a top-down view of a stiff cold plate 320 and PCB 340. The stiff cold plate 320 may have one or more connecting holes 328. The PCB 340 may have corresponding connecting holes 348 to line up with connecting holes 32 and the stiff cold plate 320. In example embodiments, a human user or automated machine may line up the connecting holes 348 above the connecting holes 328 and engage a connecting element to connect the PCB 340 to the stiff cold plate 320 by threading the connecting elements through the connecting holes 348 and 328. In some example embodiments, the connecting elements may be threaded from the connecting holes 348 to the connecting holes 328, or vice versa. The PCB 340 may include one or more heat-generating components such as CPUs 342, although in other embodiments the PCB 340 may include other heat-generating components not illustrated in FIG. 3A. The stiff cold plate 320 may also include an inlet element 312 and outlet element 314 for circulating fluid from the cooling loop corresponding to the stiff cold plate 320. As described elsewhere herein, the inlet element 312 and outlet element 314 may intake and discharge cooling fluid to and from the stiff cold plate 320 through a coolant distribution unit not illustrated in FIG. 3A.

FIG. 3B illustrates a system 304 with a stiff cold plate 320 which may connect with multiple PCBs 340. The stiff cold plate 320 may include one or more rows of connecting holes 328. As illustrated in FIG. 3B, the stiff cold plate 320 has four sets of connecting elements corresponding to four PCBs 340 or other heat-generating elements. The stiff cold plate 320 may connect to multiple PCBs 340. The stiff cold plate 320 may feature multiple rows of connecting holes 328 which align with the corresponding attachment points on each PCB 340. This configuration enables efficient thermal management across multiple components, ensuring that each PCB is adequately cooled. In example embodiments, in a data center, a stiff cold plate 320 could be used to connect to several server enclosures, allowing for a centralized cooling solution which effectively dissipates heat from multiple processors. Similarly, in industrial applications, the stiff cold plate 320 might connect to multiple heat exchangers in a manufacturing process, ensuring that all heat-generating machinery is efficiently cooled. This modular embodiment may enhance thermal performance and simplify installation and maintenance by allowing for a single, robust connection point for multiple PCBs 340.

FIG. 3C illustrates a stiff cold plate 320 with one or more temperature sensors 330A and 330B. The temperature sensors 330A and 330B may transmit one or more temperature information to the controller 350. The stiff cold plate 320 and associated temperature sensors 330A and 330B may be connected to the controller 350 through one or more wired or wireless connections. In example embodiments, these temperature sensors 330A and 330B may determine that one or more heat-generating components associated with a PCB may be approaching a threshold value such as a threshold for overheating. In response to this data, the controller 350 may communicate with a coolant distribution unit to circulate cooling fluid into the stiff cold plate through the inlet element 312. Once cooling fluid is circulating throughout the stiff cold plate 320, the temperature sensors 330A and 330B may send updated temperature information to the controller 350 which may determine that the temperature of the heat-generating components is below a threshold level (e.g., 70 degrees Celsius) for suitable operation of the heat-generating components.

In example embodiments, the temperature sensors 132 may generate temperature information and transmit it to the controller 350 and/or a user device, which may then utilize this temperature data to adjust the cooling liquid flow in the cooling loop or make determinations about the overall cooling strategy for the system. The temperature sensors 330A and 330B may include thermocouples or thermistors, which work by measuring the electrical resistance or voltage changes that occur in response to temperature variations. The temperature sensors 330A and 330B may gather temperature information by being placed in direct contact with the surface of the stiff cold plate 130 or in proximity to the PCB, allowing them to accurately gather temperature information about the heat-generating elements.

FIGS. 4A, 4B, and 4C, illustrate one or more example embodiments of a cooling loop associated with a stiff cold plate as described herein. Generally, the stiff cold plate may include one or more cooling loops in any pattern suitable to dissipate heat away from one or more heat-generating components, such as those components which might be found on a PCB. In FIG. 4A, the stiff cold plate 402 may include a cooling loop 440A comprising a single loop which snakes or zig-zag across one side of the stiff cold plate 402. The cooling loop 440A may cover a large area of the stiff cold plate 402 or indeed the entire stiff cold plate 402, including specific regions of the cooling plate that would correspond to heat generating components on the PCB like the CPU. As illustrated, the cooling loop 440A may flow through the stiff cold plate 402 via an inlet element 442 and outlet element 444 located on opposite sides of the stiff cold plate 402.

In FIG. 4B, a stiff cold plate 404 may include a cooling loop 440B comprised of several tubes or loops running from a first side of the stiff cold plate 404 to a second side of the stiff cold plate 404. As illustrated, the first and second sides may be opposite one another. In such example embodiments, the lack of turns or curvature in the cooling loop 440B may allow for quick transmission of the cooling fluid. The inlet element 442 and outlet element 444 may comprise one or more connecting elements which allow the inlet 442 and outlet element 444 to connect to the multiple cooling loops 440B. The stiff cold plate includes at least two separated loops with inlets and outlets for each loop. For example, the inlet element 442 and outlet element 444 may comprise one or more manifold inlet and outlet elements to connect to each of the individual tubes in the cooling loop 440B. This configuration ensures efficient cooling of the PCB by circulating cooling liquid through the system.

In FIG. 4C, a stiff cold plate 406 may include the cooling loop 440C which may cover only a portion of the cold plate. As illustrated, the cooling loop 440C may be proximate only a certain area (e.g., a middle portion, top portion, bottom portion, side portion, etc.) of the cold plate. This area may correspond to an area on a PCB with heat-generating components such as CPUs. Although FIG. 4C illustrates only one embodiment, it is understood that in other example embodiments, the cooling loop 440C may cover other areas of the cold plate not illustrated. For example, in other example embodiments, the cooling loop 440C may cover the middle area of the PCB (i.e., an area offset from the sides of the PCB), an area surrounding a middle of the PCB, one side of the PCB, or other configurations aimed at dissipating heat from certain areas corresponding to heat-generating elements on a PCB.

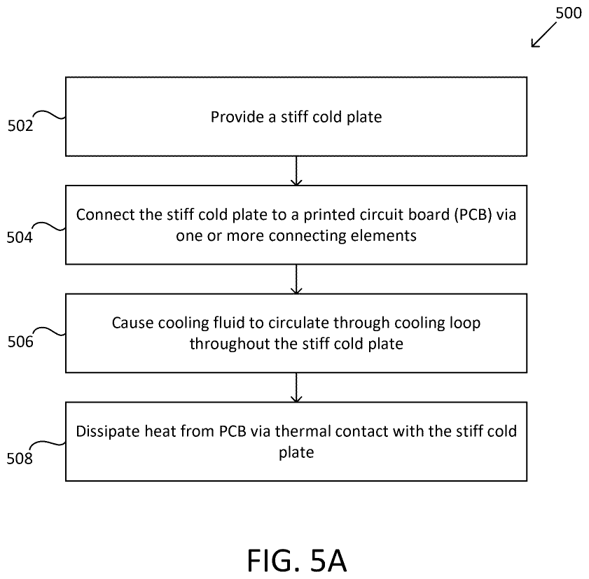

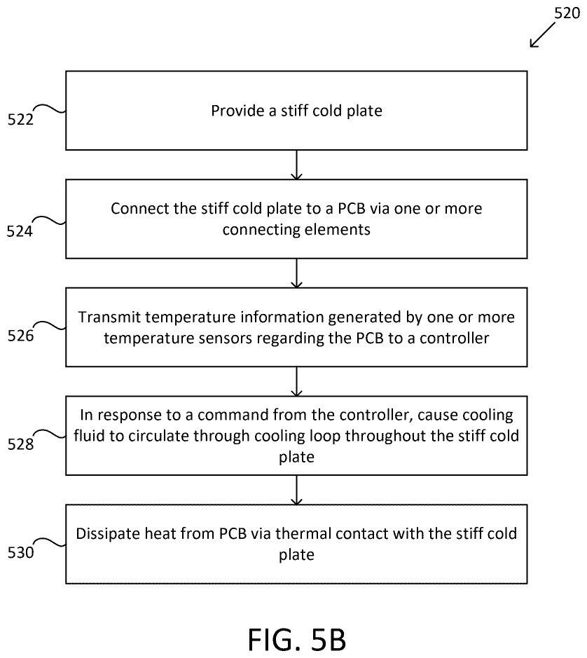

FIG. 5A illustrates a process 500 for dissipating heat from a PCB having one or more heat-generating elements. The process 500 may be implemented in various environments discussed elsewhere herein, including without limitation a data center, a server rack, or any other similar environment in which heat-generating components are cooled. Although the process 500 applies to PCBs, it is understood that in other example embodiments, the stiff cold plate may be connected to various other elements such as other processors such as graphics processing units (GPUs), power supply units, or memory modules. It should be appreciated that steps for the method may be performed in any order, or in parallel, unless otherwise specifically stated. Moreover, the method may include more or fewer steps.

A stiff cold plate may be provided 502. The stiff cold plate may be connected 504 to a PCB via one or more connecting elements. As discussed elsewhere herein, the stiff cold plate may be connected to the PCB via one or more connecting holes engaged with one or more connecting elements such as screws, fasteners, or other suitable elements. In example embodiments, a user may manually engage the connecting elements with the connecting holes of the stiff cold plate and PCB. In other example embodiments, a machine or automated apparatus may engage the connecting elements with the connecting holes. When the stiff cold plate and the PCB are removably attached to one another, cooling fluid may be circulated 506 throughout one or more cooling loops throughout the stiff cold plate. The cooling loops may transport the cooling fluid throughout the stiff cold plate or proximate one or more heat-generating elements on the PCB to dissipate 508 heat from the PCB which is in thermal contact with the stiff cold plate.

FIG. 5B illustrates a process 520 for transmitting temperature sensor information to a controller. The stiff cold plate may include one or more temperature sensors to generate temperature information regarding the PCB and/or one or more heat-generating elements. For example, the temperature sensors may generate temperature information indicating that one or more areas proximate to the PCB is reading 70 degrees Celsius or 160 degrees Fahrenheit. It should be appreciated that steps for the method may be performed in any order, or in parallel, unless otherwise specifically stated. Moreover, the method may include more or fewer steps.

A stiff cold plate may be provided 522. The stiff cold plate may be connected 524 to a PCB via one or more connecting elements. As discussed elsewhere herein, the stiff cold plate may be connected to the PCB via one or more connecting holes engaged with one or more connecting elements such as screws, fasteners, or other suitable elements. In example embodiments, a user may manually engage the connecting elements with the connecting holes of the stiff cold plate and PCB. In other example embodiments, a machine or automated apparatus may engage the connecting elements with the connecting holes. When the stiff cold plate and the PCB are removably attached to one another, one or more temperature sensors on the stiff cold plate may generate temperature information and transmit 526 the information to a controller, user device, administrative device, or other suitable device. The information may be transmitted over a wired or wireless connection. The controller may receive the temperature information and, upon determining that the temperature information indicates that the temperature corresponding to the PCB and/or one or more heat-generating elements has reached a threshold, command a CDU to circulate cooling fluid to the cold plate. In response to the command from the controller, cooling fluid may be circulated 528 through the cooling loop throughout the stiff cold plate. The cooling loops may transport the cooling fluid throughout the stiff cold plate or proximate one or more heat-generating elements on the PCB to dissipate 530 heat from the PCB which is in thermal contact with the stiff cold plate.

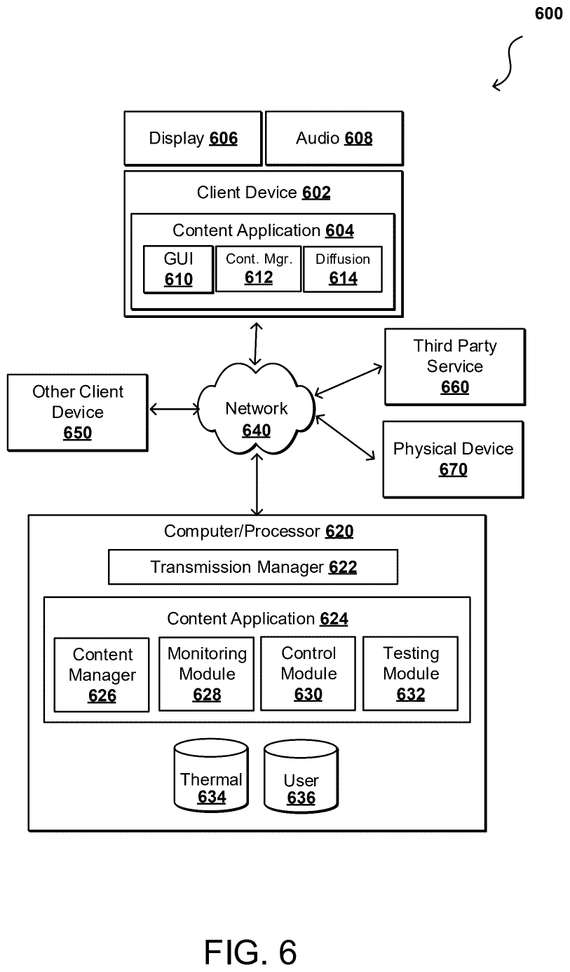

FIG. 6 illustrates an example network configuration 600 of components that can be used to implement aspects of various embodiments, such as to provide, generate, modify, encode, process, fuse, and/or transmit generated image data, calculated measurements, or other such content. In at least one embodiment, a client device 602 can generate or receive data for a session using components of a content application 604 on the client device 602 and data stored locally on that client device. In at least one embodiment, a content application 624 executing on a computer or processor 620 (e.g., a cloud server or control system) may initiate a session associated with at least one client device 602 (e.g., a vehicle or robot), as may use a session manager and user data stored in a user database 636, and can cause content such as liquid coolant or server thermal data to be selected and/or retrieved from a repository 634 to be used by a testing module 632 to calculate one or more performance metrics for a monitoring module 628, which can provide flow data or thermal data to a control module 630 to control a flow or temperature, in an environment where the data is to be used to determine appropriate operation. A content manager 626 may work with at least these various modules to perform testing and analysis, and potentially instruct any actions to be taken in response to a performance metric failing to satisfy an operational requirement. At least a portion of this data or instructional content can be transmitted to the client device 602 and/or a physical device 670 using an appropriate transmission manager 622 to send by download, streaming, or another such transmission channel. An encoder may be used to encode and/or compress at least some of this data before transmitting to the client device 602. In at least one embodiment, the client device 602 receiving such content can provide this content to a corresponding content application 604, which may also or alternatively include a graphical user interface 610, a flow monitor module 612, and a control module 614 for use in providing, synthesizing, rendering, compositing, modifying, or using content for presentation, navigation, control, (or other purposes) on or by the client device 602, such as may be transmitted to the physical device 670. In some embodiments, the computer or processor 620 and client device 602 may be able to communicate directly without needing to transmit data over a network 640, in order to avoid issues with latency and availability, etc. A decoder may also be used to decode data received over the network 640 for presentation via client device 602, such as imaging content or performance metrics through a display device 606 and audio, such as corresponding sounds or synthesized speech, through at least one audio playback device 608, such as speakers or headphones. In at least one embodiment, at least some of this content may already be stored on, rendered on, or accessible to client device 602 such that transmission over a network 640 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer or processor 620, or user database 636, to the client device 602. In at least one embodiment, at least a portion of this content can be obtained, enhanced, and/or streamed from another source, such as a third party service 660 or other client device 650, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit), (DPUs), (QPUs), a plurality of parallel processing units (PPUs).

In this example, these client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, which sits on a network edge and is outside at least one security layer associated with the cloud provider environment. In this way, latency can be reduced by enabling the client devices to interact with servers that are in closer proximity, while also improving security of resources in the cloud provider environment.

In at least one embodiment, such a system can be used for performing graphical rendering operations. In other embodiments, such a system can be used for other purposes, such as for providing image or video content to test or validate autonomous machine applications, or for performing deep learning operations. In at least one embodiment, such a system can be implemented using an edge device, or may incorporate one or more Virtual Machines (VMs). In at least one embodiment, such a system can be implemented at least partially in a data center or at least partially using cloud computing resources.

### Data Center

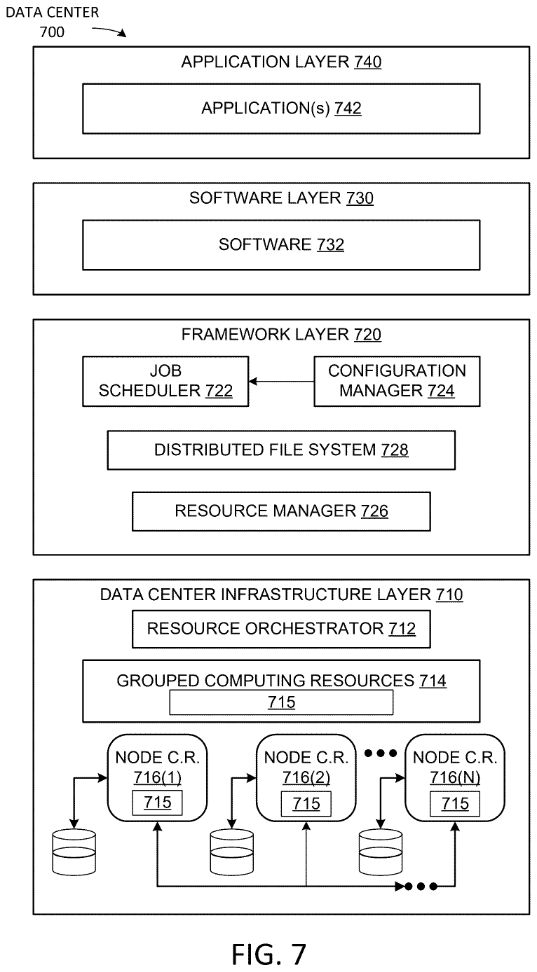

FIG. 7 illustrates an example data center 700, in which at least one embodiment may be used. In at least one embodiment, data center 700 includes a data center infrastructure layer 710, a framework layer 720, a software layer 730, and an application layer 740.

In at least one embodiment, as shown in FIG. 7, data center infrastructure layer 710 may include a resource orchestrator 712, grouped computing resources 714, and node computing resources (“node C.R.s”) 716(1)-716(N), where “N” represents any whole, positive integer. In at least one embodiment, node C.R.s 716(1)-716(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 716(1)-716(N) may be a server having one or more of above-mentioned computing resources.

In at least one embodiment, grouped computing resources 714 may include separate groupings of node C.R. s housed within one or more racks (not shown), or many racks housed in data centers at various geographical locations (also not shown). Separate groupings of node C.R.s within grouped computing resources 714 may include grouped compute, network, memory or storage resources that may be configured or allocated to support one or more workloads. In at least one embodiment, several node C.R. s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 712 may configure or otherwise control one or more node C.R.s 716(1)-716(N) and/or grouped computing resources 714. In at least one embodiment, resource orchestrator 712 may include a software design infrastructure (“SDI”) management entity for data center 700. In at least one embodiment, resource orchestrator may include hardware, software or some combination thereof.

In at least one embodiment, as shown in FIG. 7, framework layer 720 includes a job scheduler 722, a configuration manager 724, a resource manager 726 and a distributed file system 728. In at least one embodiment, framework layer 720 may include a framework to support software 732 of software layer 730 and/or one or more application(s) 742 of application layer 740. In at least one embodiment, software 732 or application(s) 742 may respectively include web-based service software or applications, such as those provided by Amazon Web Services, Google Cloud and Microsoft Azure. In at least one embodiment, framework layer 720 may be, but is not limited to, a type of free and open-source software web application framework such as Apache Spark™ (hereinafter “Spark”) that may use distributed file system 728 for large-scale data processing (e.g., “big data”). In at least one embodiment, job scheduler 722 may include a Spark driver to facilitate scheduling of workloads supported by various layers of data center 700. In at least one embodiment, configuration manager 724 may be capable of configuring different layers such as software layer 730 and framework layer 720 including Spark and distributed file system 728 for supporting large-scale data processing. In at least one embodiment, resource manager 726 may be capable of managing clustered or grouped computing resources mapped to or allocated for support of distributed file system 728 and job scheduler 722. In at least one embodiment, clustered or grouped computing resources may include grouped computing resource 714 at data center infrastructure layer 710. In at least one embodiment, resource manager 726 may coordinate with resource orchestrator 712 to manage these mapped or allocated computing resources.

In at least one embodiment, software 732 included in software layer 730 may include software used by at least portions of node C.R.s 716(1)-716(N), grouped computing resources 714, and/or distributed file system 728 of framework layer 720. The one or more types of software may include, but are not limited to, Internet web page search software, e-mail virus scan software, database software, and streaming video content software.

In at least one embodiment, application(s) 742 included in application layer 740 may include one or more types of applications used by at least portions of node C.R.s 716(1)-716(N), grouped computing resources 714, and/or distributed file system 728 of framework layer 720.

One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 724, resource manager 726, and resource orchestrator 712 may implement any number and type of self-modifying actions based on any amount and type of data acquired in any technically feasible fashion. In at least one embodiment, self-modifying actions may relieve a data center operator of data center 700 from making possibly bad configuration decisions and possibly avoiding underused and/or poor performing portions of a data center.

In at least one embodiment, data center 700 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 700. In at least one embodiment, trained machine learning models corresponding to one or more neural networks may be used to infer or predict information using resources described above with respect to data center 700 by using weight parameters calculated through one or more training techniques described herein.

In at least one embodiment, a data center may use CPUs, application-specific integrated circuits (ASICs), GPUs, FPGAs, DPUs, QPUs, a plurality of parallel processing units (PPUs), or other hardware to perform training and/or inferencing using above-described resources.

Moreover, one or more software and/or hardware resources described above may be configured as a service to allow users to train or perform inferencing of information, such as image recognition, speech recognition, or other artificial intelligence services.

Inference and/or training logic 715 are used to perform inferencing and/or training operations associated with one or more embodiments. In at least one embodiment, inference and/or training logic 715 may be used in system FIG. 7 for inferencing or predicting operations based, at least in part, on weight parameters calculated using neural network training operations, neural network functions and/or architectures, or neural network use cases described herein.

Such components can be used in data centers that use stiff cold plates and cooling loops as described herein.

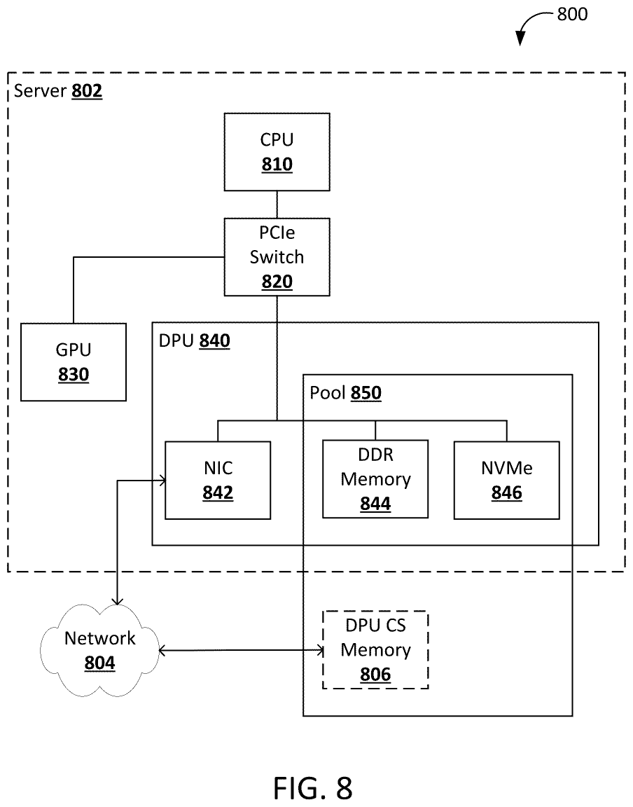

FIG. 8 illustrates an example computing environment 800 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 800 may include a server 802 which may be used to perform HPC workloads, such as AI training or machine learning model training. In an embodiment, the server 802 may be an application instance or a compute node. The server 802 may include a CPU 810 associated with a switch 820, such as a peripheral component interconnect express (PCIe) switch, which may control at least some data transmission over communication paths interconnecting various components. In an embodiment, the CPU 810 may include a root complex processor.

The PCIe switch 820 may also be associated with a GPU 830 and a DPU 840, and may transmit data between at least some of the CPU 810, the GPU 830, the DPU 840, and other components. In an embodiment, the PCIe switch 820 may be associated with more than one GPU or more than one DPU. In another embodiment, the PCIe switch 820 may be located within the DPU 840. The PCIe switch 820 may manage the transfer of at least some data between the CPU 810, the GPU 830, and the DPU 840. In another embodiment, the number of GPUs associated with the PCIe switch 820 may be equal to the number of DPUs associated with the PCIe switch 820. In at least one embodiment, the server 802 may include, without limitation, any number of the CPUs 810, the PCIe switches 820, the GPUs 830, and/or the DPUs 840, in any combination. For example, in at least one embodiment, server 802 could include eight, sixteen, thirty-two, and/or more GPUs 830. In at least one embodiment, communication paths interconnecting various components, including but not limited to the CPU 810, the PCIe switch 820, the GPU 830, and the DPU 840, in FIG. 8 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 840 may include a network interface controller (NIC) 842, a DDR memory 844, and a non-volatile memory express (NVMe) device 846. The NIC 842 may be able to interface with a network 804, which may also interface with additional NVMe devices available to the DPU 840, such as over fabric. In an embodiment, the DPU 840 may not include the NVMe device 846. In another embodiment, the NVMe device 846 may be located on the server 802 and not on the DPU 840. In yet another embodiment, the computing environment 800 may include more than one of the NVMe device 846, such as a first NVMe device in the DPU 840 and a second first NVMe device on the server 802, and associated directly with the PCIe switch 820. In an embodiment, the DPU 840 may not include the DDR memory 844 and may include a computational storage services (CSS) in place of, or in addition to, the DDR memory 844. For example, computing environment 800 may include DPU computational storage (CS) memory 806 available to the DPU 840 as part of the CSS. The network 804 may be able to interface with the DPU CS memory 806 through the NIC 842, according to any suitable interface protocol, such as remote direct memory access (RDMA) over Ethernet, InfiniBand, Fiber Channel, etc.

The total memory of the computing environment 800 available for data storage may be expanded through the use of the DPU 840 on nodes of the system. The DPU 840 may have access to a pool 850 of memory already available to the server 802, such as double data rate (DDR) memory, on-board NVMe devices, NVMe devices over fabric, and CS. The pool 850 of memory may include at least one of the DDR memory 844, NVMe 846, and the DPU CS memory 806. The DPU 840 may also be able to access the available memory of other DPUs as part of the pool 850, and other DPUs may be able to access the available memory of DPU 840, such as the pool 850. This available memory can be accessed and utilized for data storage, without the addition of compute resources, such as compute nodes, which would be required using other solutions. The available pool 850 accessible to the DPU 840 may be provisioned for the server 802 to expand the total memory available for data storage, such as to reduce the data storage load on the CPU 810 or the GPU 830, which can instead increase the utilization of their memory for processing. For example, during training of an AI, the model states, residual states, activation functions, and checkpoints can be stored, or offloaded, on the pool 850 accessible to the DPU 840.

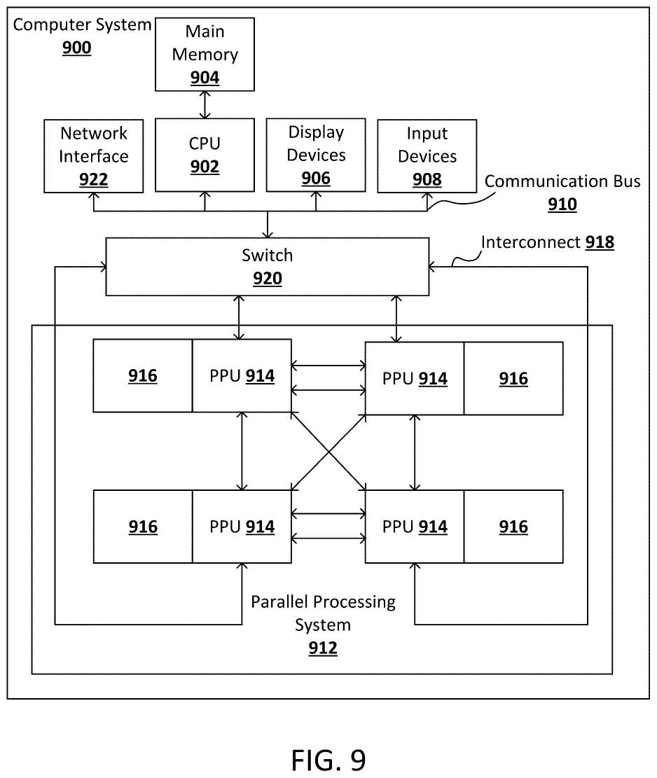

FIG. 9 illustrates a computer system 900, according to at least one embodiment. In at least one embodiment, computer system 900 is configured to implement various processes and methods described throughout this disclosure.

In at least one embodiment, computer system 900 comprises, without limitation, at least one central processing unit (“CPU”) 902 that is connected to a communication bus 910 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 900 includes, without limitation, a main memory 904 and control logic (e.g., implemented as hardware, software, or a combination thereof) and data are stored in main memory 904 which may take form of random access memory (“RAM”). In at least one embodiment, a network interface subsystem (“network interface”) 922 provides an interface to other computing devices and networks for receiving data from and transmitting data to other systems from computer system 900.

In at least one embodiment, computer system 900, in at least one embodiment, includes, without limitation, input devices 908, parallel processing system 912, and display devices 906 which can be implemented using a conventional cathode ray tube (“CRT”), liquid crystal display (“LCD”), light emitting diode (“LED”), plasma display, or other suitable display technologies. In at least one embodiment, user input is received from input devices 908 such as keyboard, mouse, touchpad, microphone, and more. In at least one embodiment, each of the foregoing modules can be situated on a single semiconductor platform to form a processing system.

In at least one embodiment, computer programs in form of machine-readable executable code or computer control logic algorithms are stored in main memory 904 and/or secondary storage. Computer programs, if executed by one or more processors, enable system 900 to perform various functions in accordance with at least one embodiment. Memory 904, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 902; parallel processing system 912; an integrated circuit capable of at least a portion of capabilities of both CPU 902; parallel processing system 912; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 900 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 912 includes, without limitation, a plurality of parallel processing units (“PPUs”) 914 and associated memories 916. In at least one embodiment, PPUs 914 are connected to a host processor or other peripheral devices via an interconnect 918 and a switch 920 or multiplexer. In at least one embodiment, parallel processing system 912 distributes computational tasks across PPUs 914 which can be parallelizable-for example, as part of distribution of computational tasks across multiple graphics processing unit (“GPU”) thread blocks. In at least one embodiment, memory is shared and accessible (e.g., for read and/or write access) across some or all of PPUs 914, although such shared memory may incur performance penalties relative to use of local memory and registers resident to a PPU 914. In at least one embodiment, operation of PPUs 914 is synchronized through use of a command such as_syncthreads( ), wherein all threads in a block (e.g., executed across multiple PPUs 914) to reach a certain point of execution of code before proceeding.

Such components can be used in data centers that use stiff cold plates and cooling loops as described herein.

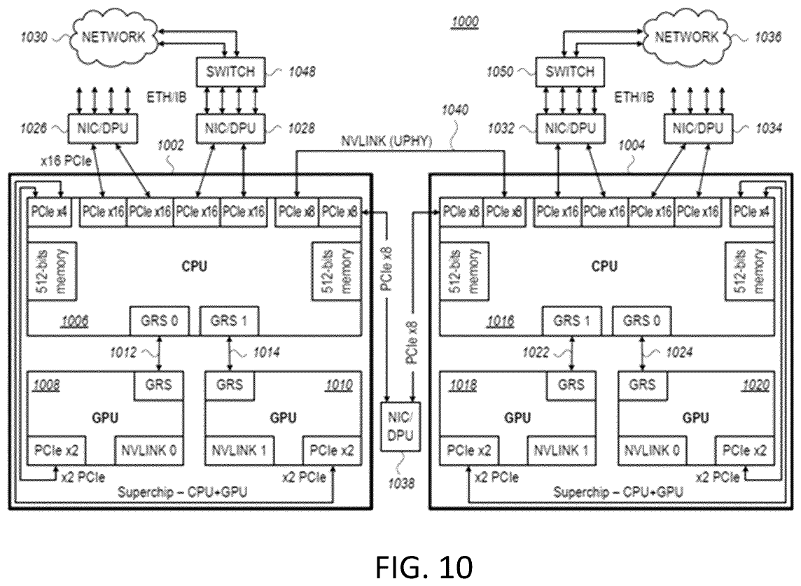

FIG. 10 is a block diagram that schematically illustrates a computing system 1000, e.g., a data center or a High-Performance Computing (HPC) cluster, in accordance with an embodiment that is described herein. System 1000 comprises a plurality of subsystems, e.g., multiple processing devices coupled to each other, multiple network devices, and multiple networks, according to at least one embodiment. Computing system 1000 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1000 and to one or more external networks 1030, 1036. In the present example, system 1000 comprises a switch 1048 that connects NIC/DPU 1028 to network 1030, and a packet switch 1050 that connects NIC/DPU 1032 to network 1036.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1000 can include one or more CPUs and one or more GPUs.

FIG. 10 also demonstrates an example architecture of a multi-GPU architecture. As illustrated in the figure, computing system 1000 includes a processing device 1002 with a multi-GPU architecture. In particular, processing device 1002 may be a system-on-chip and includes multiple subsystems such as a CPU 1006, a GPU 1008, and a GPU 1010. CPU 1006 can be coupled to GPU 1008 via a die-to-die (D2D) or chip-to-chip (C2C) interconnect 1012, such as a Ground-Referenced Signaling interconnect (GRS interconnect). CPU 1006 can be coupled to GPU 1010 via a D2D or C2C interconnect 1014. CPU 1006 can also couple to GPU 1008 and GPU 1010 via PCIe interconnects.

CPU 1006 can be coupled to one or more NICs or DPUs, which are coupled to one or more networks. For example, as illustrated in FIG. 10, CPU 1006 is coupled to a first NIC/DPU 1026, which is coupled to a network 1030. CPU 1006 is also coupled to a second NIC/DPU 1028, which is coupled to network 1030 via switch 1048. NIC/DPU 1026 and NIC/DPU 1028 can be coupled to network 1030 over Ethernet (ETH), NVLINK or InfiniBand (IB) connections, for example.

Computing system 1000 also includes a processing device 1004 with a multi-GPU architecture. In particular, processing device 1004 includes multiple subsystems including a CPU 1016, a GPU 1018, and a GPU 1020. CPU 1016 can be coupled to GPU 1018 via a D2D or C2C interconnect 1022. CPU 1016 can be coupled to GPU 1020 via a D2D or C2C interconnect 1024. CPU 1016 can also couple to GPU 1018 and GPU 1020 via PCIe interconnects. CPU 1016 can be coupled to one or more NICs or DPUs, which are coupled to one or more networks. For example, as illustrated in FIG. 10, CPU 1016 is coupled to a first NIC/DPU 1032, which is coupled to a network 1036. CPU 1016 is also coupled to a second NIC/DPU 1034, which is coupled to network 1036 via switch 1050. NIC/DPU 1032 and NIC/DPU 1034 can be coupled to network 1036 over Ethernet (ETH), NVLINK or InfiniBand (IB) connections.

In at least one embodiment, processing device 1002 and processing device 1004 can communicate with each other via a NIC/DPU 1038, such as over PCIe interconnects. Processing device 1002 and processing device 1004 can also communicate with each other over a high-bandwidth communication interconnects 1040, such as an NVLink interconnect or other high-speed interconnects. The packet switches in FIG. 10 may comprise, for example, Nvidia Quantum-2 switches. The NICs/DPUs in the figure may comprise, for example, Nvidia Bluefield DPUs.

In various embodiments, any of the network devices of system 1000, e.g., any of NICs/DPUs 1026, 1028, 1032, 1034 and 1038, and/or any of switches 1048 and 1050, may use ILI packets in accordance with the techniques described herein. Such components can be used in data centers that use liquid cooling systems.

In example embodiments, the heat-generating element may be a silicon photonics element (e.g., SiPh die) or photonic IC. The elements may be Co-packaged forming a multichip-module (MCM) assembly.

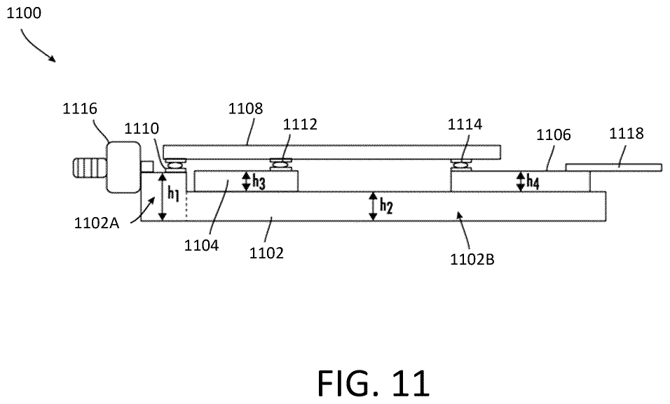

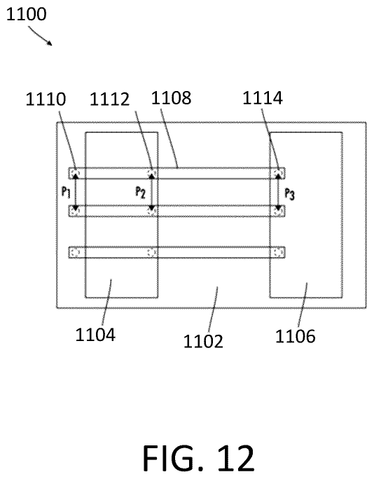

With reference to FIGS. 11 and 12, a cross-sectional view and a top plan view, respectively, of an optoelectronic component 1100 are illustrated. In some embodiments, the optoelectronic component 1100 may include a substrate 1102. The substrate 1102, for example, may be a printed circuit board, a metal carrier, an organic carrier, and/or a ceramic carrier. In some embodiments, the height of the substrate 1102 may vary. In this regard, for example, a first portion 1102A of the substrate 1102 may have a height h1 and a second portion 1102B of the substrate 1102 may have a height h2. In some embodiments, an electronic integrated circuit 1104 may be supported by the substrate 1102. The electronic integrated circuit 1104 may be any type of electronic integrated circuit. For example, the electronic integrated circuit 1104 may be a digital signal processor, a modulator driver, and/or a transimpedance amplifier. In some embodiments, there may be more than one electronic integrated circuit supported by the substrate 1102. In some embodiments, the electronic integrated circuit 1104 may have a height h3. In some embodiments, the optoelectronic component 1100 may support more than one electronic integrated circuit. In some embodiments, a photonic integrated circuit 1106 may be supported by the substrate 1102. The photonic integrated circuit 1106 may be any type of photonic integrated circuit. For example, the photonic integrated circuit 1106 may be an electro-optic modulator, a photodiode, a transmitter optical sub assembly and/or a receiver optical sub assembly. In some embodiments, the photonic integrated circuit 1106 may comprise graphene. In some embodiments, there may be more than one photonic integrated circuit supported by the substrate 1102. In some embodiments, the photonic integrated circuit 1106 may have a height h4. In some embodiments, the heights h1, h2, h3, and h4 may be different. For example, depending on the electronic integrated circuit and photonic integrated circuit used, the height h3 may be greater than the height h4, or vice versa.

In some embodiments, the optoelectronic component 1100 may include one or more optical fibers 1118 connected to the photonic integrated circuit 1106. The one or more optical fibers 1118 may be configured to connect the optoelectronic component 1100 to other optical components and/or devices. In some embodiments, a port 1116 may be connected to the substrate 1102. The port 1116 may be configured to connect the optoelectronic component 1100 to other electronic components and/or devices. In some embodiments, the optoelectronic component 1100 may be configured to operate at speeds greater than 25 Gb/s.

The optoelectronic component 1100 may include a plurality of substrate interconnect connectors 1110 disposed on the substrate 1102, a plurality of electronic integrated circuit interconnect connectors 1112 disposed on the electronic integrated circuit 1104, and a plurality of photonic integrated circuit interconnect connectors 1114 disposed on the photonic integrated circuit 1106. The plurality of substrate interconnect connectors 1110, the plurality of electronic integrated circuit interconnect connectors 1112, and the plurality of photonic integrated circuit interconnect connectors 1114 may comprise any conductive material (e.g., conductive glue and/or solder). In some embodiments, the plurality of substrate interconnect connectors 1110, the plurality of electronic integrated circuit interconnect connectors 1112, and the plurality of photonic integrated circuit interconnect connectors 1114 may be flexible. In other words, in some embodiments, the plurality of substrate interconnect connectors 1110, the plurality of electronic integrated circuit interconnect connectors 1112, and the plurality of photonic integrated circuit interconnect connectors 1114 may be manipulated such that each may be capable of taking various shapes. In some embodiments, the plurality of substrate interconnect connectors 1110 may have a pitch p1, the plurality of electronic integrated circuit interconnect connectors 1112 may have a pitch p2, and the plurality of photonic integrated circuit interconnect connectors 1114 may have a pitch p3. The pitch may refer to the distance between each of the plurality of interconnect connectors. In some embodiments, the pitch p1, pitch p2, pitch p3, may be different. For example, the pitch p2 of the plurality of electronic integrated circuit interconnect connectors 1112 may be 1.25 mm while the pitch p3 of the plurality of photonic integrated circuits may be 1.5 mm.

In some embodiments, the optoelectronic component 1100 may include a first plurality of cable connectors 1108. In some embodiments, each of the first plurality of cable connectors 1108 may be connected to and in communication with the substrate 1102, the electronic integrated circuit 1104, and the photonic integrated circuit 1106 via respective interconnect connectors. In other words, the first plurality of cable connectors 1108 may be connected to and in communication with the substrate 1102 via the plurality of substrate interconnect connectors 1110, the electronic integrated circuit 1104 via the plurality of electronic integrated circuit interconnect connectors 1112, and the photonic integrated circuit 1106 via the plurality of photonic integrated circuit interconnect connectors 1114. As such, the first plurality of cable connectors 1108 may be used to facilitate communication between the substrate 1102, the electronic integrated circuit 1104, and the photonic integrated circuit 1106.

In some embodiments, the first plurality of cable connectors 1108 may define a first layout. In some embodiments, the first layout may define the overall connectivity of the optoelectronic component 1100.

In some embodiments, the optoelectronic component 1100 may include a substrate 1102. The substrate 1102, for example, may be a printed circuit board, a metal carrier, an organic carrier, and/or a ceramic carrier.

The electronic integrated circuit 1104 may be any type of electronic integrated circuit. For example, the electronic integrated circuit 1104 may be a digital signal processor, a modulator driver, and/or a transimpedance amplifier. In some embodiments, there may be more than one electronic integrated circuit supported by the substrate 1102.

In some embodiments, a photonic integrated circuit 1106 may be supported by the substrate 1102. The photonic integrated circuit 1106 may be any type of photonic integrated circuit. For example, the photonic integrated circuit 1106 may be an electro-optic modulator, a photodiode, a transmitter optical sub assembly and/or a receiver optical sub assembly.

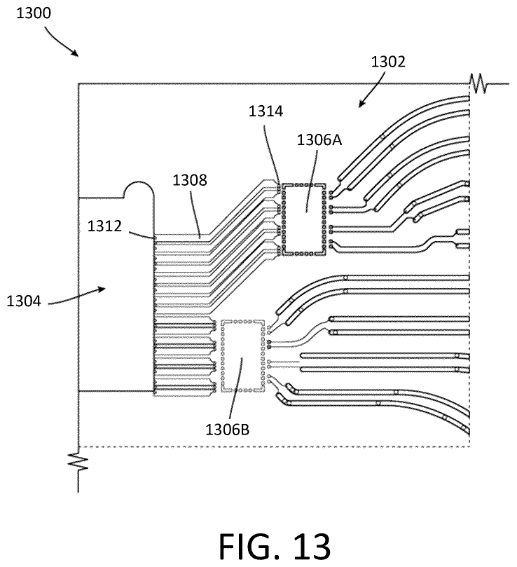

For example, with reference to FIG. 13, the connectivity defined by the first layout in the illustrated example is such that an electronic integrated circuit 1304 is connected to a first photonic integrated circuit 1306A and a second photonic integrated circuit 1306B via cable connectors 1308. In some embodiments, the first plurality of cable connectors 1308 may be interchangeable with other pluralities of cable connectors that define different layouts. The different layouts may alter the overall connectivity of the optoelectronic component 1300. For example, the first plurality of cable connectors 1308 may be interchangeable with a second plurality of cable connectors that define a second layout which modifies the overall connectivity of the optoelectronic component 1300. In this way, the optoelectronic component 1300 may be easily modified to obtain desired capabilities by interchanging cable connectors.

In some embodiments, the first plurality of cable connectors 1308 may be flexible. This may help ensure that the first plurality of cable connectors 1308 may be used with a variety of substrates, electronic integrated circuits, and photonic integrated circuits. For example, the substrate, electronic integrated circuit, and/or photonic integrated circuit may be from different manufacturers, may be a different type of integrated circuit or substrate, and/or may have different capabilities. For example, the substrate 1302, electronic integrated circuit 1304, and the photonic integrated circuit 1306A, 1306B may have different heights (e.g., height h3 of the electronic integrated circuit 1304 may be greater than height h4 of the photonic integrated circuit 1306A, 1306B). The flexibility of the first plurality of cable connectors 1308 enables the first plurality of cable connectors 1308 to bend as needed, such that components of the optoelectronic component 1300 with different heights may be accommodated and connections may be made without any modifications to the configuration of the optoelectronic component 1300 itself. Additionally, the flexibility of the first plurality of cable connectors 1308 may enable the first plurality of cable connectors 1308 to be used with a variety of substrates, electronic integrated circuits, and photonic integrated circuits that have interconnect connectors with different pitches. For example, if the pitch p2 of the plurality of electronic integrated circuit interconnect connectors 1312 is less than the pitch p3 of the plurality of photonic integrated circuit interconnect connectors 1314, the first plurality of cable connectors 1308 may bend to account for the differences in pitch and connect the electronic integrated circuit 1304 to the photonic integrated circuit 1106.

With reference to FIG. 13, a portion of an example optoelectronic component 1300 is illustrated. For example, the example optoelectronic component 1300 may be part of a 1.6 Tb/s demonstrator. The example optoelectronic component 1300 includes a substrate 1302, an electronic integrated circuit 1304 supported by the substrate 1302, a first photonic integrated circuit 1306A supported by the substrate 1302, and a second photonic integrated circuit 1306B supported by the substrate 1302. The example optoelectronic component 1300 may include a plurality of electronic integrated circuit interconnect connectors 1312 disposed on the electronic integrated circuit 1304 and a plurality of photonic integrated circuit interconnect connectors 1314 disposed on the first photonic integrated circuit 1306A and the second photonic integrated circuit 1306B. The electronic integrated circuit 1304 may be connected to and in communication with the first photonic integrated circuit 1306A and the second photonic integrated circuit 1306B via a plurality of cable connectors 1308. In the example optoelectronic component 1300, the electronic integrated circuit 1304 and the first photonic integrated circuit 1306A are situated on the substrate 1302 such that the plurality of electronic integrated circuit interconnect connectors 1312 and the plurality of photonic integrated circuit interconnect connectors 1314 disposed on the first photonic integrated circuit 1306A are not aligned with each other (e.g., one is not disposed directly opposite to the other). In such a situation, the flexibility of the plurality of cable connectors 1308 facilitating communication between the electronic integrated circuit 1304 and the first photonic integrated circuit 1306A may allow the electronic integrated circuit 1304 and the first photonic integrated circuit 1306A to be connected through manipulation of the cable connectors to accommodate the misaligned locations.

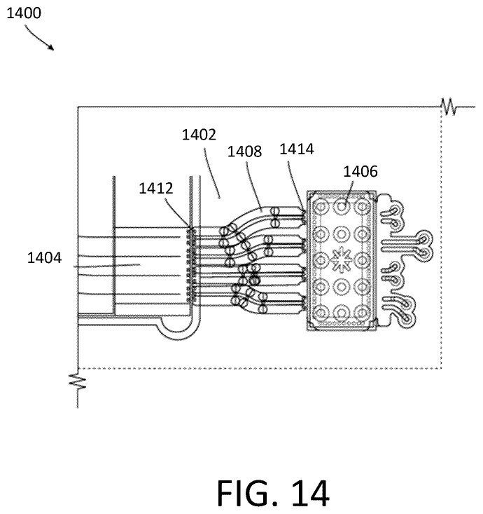

With reference to FIG. 14, another example optoelectronic component 1400 is illustrated. For example, the example optoelectronic component 1400 may be part of an octal small form factor pluggable (OSFP) transceiver. The example optoelectronic component 1400 includes a substrate 1402, an electronic integrated circuit 1404 supported by the substrate 1402, and a photonic integrated circuit 1406 supported by the substrate 1402. The example optoelectronic component 1400 may include a plurality of electronic integrated circuit interconnect connectors 1412 disposed on the electronic integrated circuit 1404 and a plurality of photonic integrated circuit interconnect connectors 1414 disposed on the photonic integrated circuit 1406. The electronic integrated circuit 1404 may be connected to and in communication with the photonic integrated circuit 1406 via a plurality of cable connectors 1408. In the example optoelectronic component 1400, the pitch of the plurality of the electronic integrated circuit interconnect connectors 1412 and the plurality of photonic integrated circuit interconnect connectors 1414 is different. In this case, the flexibility of the plurality of cable connectors 1408 facilitating communication between the electronic integrated circuit 1404 and the photonic integrated circuit 1406 may be such that the electronic integrated circuit 1404 and the photonic integrated circuit 1406 can be connected despite the differences in pitch, such as through bending or other reshaping of the cable connectors to accommodate the differences.

Silicon Photonics (SiP) is a technology that enables optical systems to be manufactured using silicon processes with silicon as the optical medium. Various optical components, such as interconnects and signal processing components, may be fabricated and integrated in a single SiP device. Some SiP devices are fabricated on a silica substrate or over a silica layer on a silicon substrate, a technology that is often referred to as Silicon on Insulator (SOI). In certain optical systems, a SiP device is attached to an external device to facilitate optical communications. However, it is generally difficult to accurately align light signals on the SiP with an external device that receives the light.

In certain optical systems, a SiP device is attached to an external device to facilitate optical communications. However, it is generally difficult to accurately align light signals on the SiP with an external device that receives the light. For instance, long range transmission of light signals is generally performed within optical fibers. When optical signals are generated or processed in a SiP device for transmission over optical fibers, the light needs to be coupled between the SiP device and the optical fibers. This coupling between the SiP device and the optical fibers is generally difficult because waveguides within the SiP device generally comprise a smaller diameter than the optical fibers. As such, a “world-to-chip” interface problem often arises in SiP technologies where coupling of light between Si wire waveguides and optical fibers, and vice versa, is generally inefficient.

Traditionally, for fiber-to-chip coupling, a fiber coupling technique using spot-size converters (SSCs) or grating couplers is employed. However, grating couplers for fiber-to-chip coupling typically provide a narrow bandwidth and/or an undesirable polarization sensitivity for certain optical applications. Furthermore, SSCs and grating couplers for fiber-to-chip coupling are generally attached to the chip through an adhesive bonding technique that results in a silicon communication chip with bundles of fibers attached thereto, resulting in increased complexity for handling and/or assembly of the chips onto other optical systems. Additionally, wafers for traditional SiP devices are generally diced (e.g., fully cut through) to create an edge for the wafer to expose waveguide facets and/or to facilitate butt attachment of the SiP device to an external device. Co-packaging may refer to the close integration of different electrical and/or optoelectronic chips in the same package.

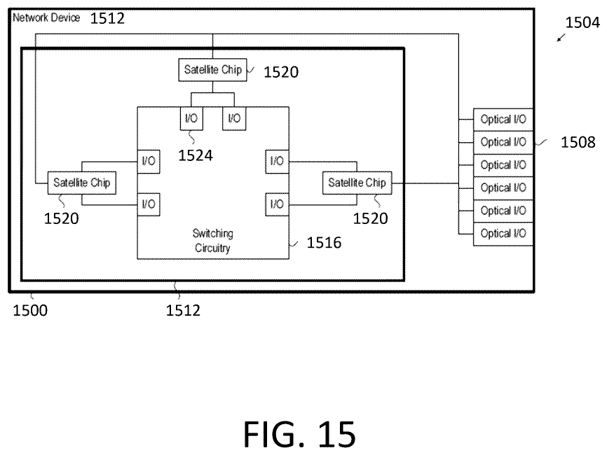

FIG. 15 is a block diagram that schematically illustrates a co-packaged Networking Device 1500, in accordance with an embodiment that is disclosed herein. The different chips that constitute a co-packaged Networking Device are assembled on a single substrate in what is typically called the MCM assembly 1512. The MCM assembly 1512 can include a switching circuitry 1516 surrounded by peripheral or satellite chips 1520. In some embodiments, the switching circuitry 1516 and surrounding satellite chips 1520 are all mounted on a common substrate, although such a configuration is not required. The MCM assembly 1512 may be provided in a larger housing of the co-packaged Networking Device 1500, positioned behind the front panel 1504. The switching circuitry 1516 may include one or more core digital Application Specific Integrated Circuits (ASICs), CPUs, GPUs, microprocessors, FPGAs, combinations thereof, and the like. The switching circuitry 1516 may include a number of input ports and/or output ports 1524. The Input/Output (I/O) ports 1524 may include electrical ports and/or optical ports. Additionally, the switching circuitry 1516 may include a combination of electrical blocks and optical blocks. The electrical blocks of the switching circuitry 1516 may include a number of electrical switches that are configured to route signals in an electrical domain. The optical blocks of the switching circuitry 1516 may include a number of optical components that are configured to generate, detect and route signals in an optical domain. The MCM assembly 1512, in some embodiments, may concern or include multiple satellite chips 1520 that are assembled on the same substrate as the switching circuitry 1516. In some embodiments, a configuration of the optical block(s) and a configuration of the electrical block(s) depends (e.g., is based on) on the number of optical ports in the I/O ports 1524.

As discussed above, optical I/Os 1508, which may also be referred to as optical connectors, are placed at the front panel 1504. As mentioned above, connectivity between the MCM assembly 1512 and optical I/Os 1508 may be transferred to the front panel 1504 through optical fibers. This connection may be made directly with an optical I/O port 1524 of the switching circuitry or may be made with one or more of the satellite chips 1520. The connection is often made with one or more of the satellite chips 1520 because the satellite chips 1520 may include the electro-optic converters and, possibly, the SERDES to natively support the connection. The satellite chips 1520 may include one or more of a DSP processor, driver, transimpedance amplifier, laser, modulator, photodiode, serializer-deserializer, or the like.

Some embodiments of the present disclosure are directed to a multi-chip module (MCM) with a centrally positioned main die and a plurality of peripherally positioned MCM sockets configured to mechanically receive and electrically connect mezzanine packages, which may include co-packaged optics (CPO) packages and co-packaged copper (CPC) packages. Each mezzanine package may include a package substrate including a connector portion that is configured to engage the MCM socket and a main portion extending beyond the periphery of the MCM substrate. The main portion of the mezzanine package may be configured to receive optical devices and/or integrated circuits, such as via mezzanine sockets, to allow connections to be made between the optical devices and/or integrated circuits/RF copper cable connectors and the main die of the MCM. Due to the extension of the mezzanine package beyond the periphery of the MCM substrate, the physical size of the MCM substrate may remain small to reduce cost and avoid the previously discussed production challenges, while allowing connections to a number of optical devices and integrated circuits via the mezzanine packages, which occupy the relatively inexpensive space around the periphery of the MCM substrate. As used herein, the terms “co-packaged optic” (or “CPO”) and “co-packaged copper” (or “CPC”) may refer to an advanced heterogeneous integration of either optics and silicon or copper and silicon, in which either integration may be implemented on a single packaged substrate. The CPO may utilize pluggable optical modules that include an optical engine (OE) to convert optical signals to electrical signals and electrical signals to optical signals. The CPO may further be comprised of an optical component on a photonics die and an electrical component on an electrical die.

As used herein, a ball grid array (BGA) may be a type of surface-mount packaging used for integrated circuits. BGA packages use an array of metallic conductor balls arranged in a grid to permanently mount devices such as microprocessors on a PCB. The metallic conductor balls may then undergo the reflow process described above, wherein the metallic conductor balls may be preheated, then melted to bond the IC to a substrate to form an IC package.

As used herein, the term “flip chip (FC)” may refer to a method for interconnecting dies, such as semiconductor devices, IC chips, integrated passive devices, and microelectromechanical systems (MEMS), to external circuitry with solder bumps that have been deposited onto chip pads. The solder bumps may be deposited onto chip pads on the top side of the wafer during final wafer processing. The chip may be mounted to external circuitry (such as a circuit board or another chip or wafer) by “flipping” the chip, such that the chip's top side faces down and is positioned to allow the pads of the chip to align with matching pads on the external circuit. Solder is reflowed to complete the interconnect.

In the packaging of integrated circuit (IC) chips, various packaging schemes are employed, including traditional two-dimensional (2D) integrated circuit (IC) packages as well as the more recently introduced 2.5D IC and 3D IC packages. In 2D IC packages, multiple chips are mounted on a printed circuit board, where high-performance logic, lower-performance logic, memory, and analog/RF functions, and other functional elements are presented as discrete devices in separate chip packages. By contrast, in 2.5D ICs and 3D IC packages, multiple IC chips are mounted on a silicon interposer instead of a conventional package substrate. The silicon interposer, which is typically a silicon wafer, allows very small and high-density conductive traces to be formed between the multiple IC chips because the fabrication processes used to form the conductive traces are the same processes used to form the metal interconnects in the metalization layers of a silicon chip.

Compared to 2.5D IC packages and 3D IC packages, a circuit board with individually packaged chips, such as a 2D IC package, has numerous disadvantages. For example, a 2D IC package is generally larger, heavier, consumes more power, and, because the signals propagate relatively slowly across the circuit board from one chip to another, is slower than an equivalent 2.5D or 3D IC package. Furthermore, a 2D IC package has more possible points of failure, given that the soldered joints on the circuit board are more likely to fail than the electrical connections formed within an interposer. That said, troubleshooting a 2D IC package after the different chips have been mounted on the circuit board is relatively straightforward. In particular, the conductive traces carrying I/O signals between the various chips on the circuit board are easily accessible and therefore can be employed to measure specific I/O signals during troubleshooting.

By contrast, troubleshooting a 2.5D or 3D IC package is far more problematic because the I/O signals transmitted between the different chips typically are embedded in the silicon interposer and are not physically accessible. Furthermore, because 2.5D and 3D IC packages are high-bandwidth and are quite dense, typically implementations can include thousands of conductive traces routed between the different chips. One example of such an implementation is a memory bus residing in between a processor and a high-bandwidth memory chip. In such implementations, even if the traces could be physically accessed through the silicon interposer with a probe, the accurate and reliable selection of a specific conductive trace or combination of conductive traces for the purpose of troubleshooting the IC package would be very difficult, if not impossible.

In at least one embodiment, one or more parallel processor(s) incorporate circuitry optimized for graphics and video processing, including, for example, video output circuitry, and constitutes a graphics processing unit (“GPU”). In at least one embodiment, one or more parallel processor(s) incorporate circuitry optimized for general purpose processing. In at least one embodiment, components of computing system may be integrated with one or more other system elements on a single integrated circuit. For example, in at least one embodiment, one or more parallel processor(s), memory hub, processor(s), and I/O hub can be integrated into a SoC integrated circuit. In at least one embodiment, components of computing system can be integrated into a single package to form a system in package (“SIP”) configuration. In at least one embodiment, at least a portion of components of computing system 300 can be integrated into a multi-chip module (“MCM”), which can be interconnected with other multi-chip modules into a modular computing system. In at least one embodiment, I/O subsystem and display devices are omitted from computing system.

When the light-transmitting medium is silicon, a suitable insulator includes, but is not limited to, silica and a suitable substrate includes a silicon substrate. A silicon-on-insulator wafer is a suitable platform for an optical device having a silicon light-transmitting medium positioned over a base having a silica insulator and a silicon substrate.

The device includes one or more waveguides that carry light signals to and/or from optical components. Examples of optical components that can be included on the device include, but are not limited to, one or more components selected from a group consisting of facets through which light signals can enter and/or exit a waveguide, entry/exit ports through which light signals can enter and/or exit a waveguide from above or below the device, multiplexers for combining multiple light signals onto a single waveguide, demultiplexers for separating multiple light signals such that different light signals are received on different waveguides, optical couplers, optical switches, lasers that act as a source of a light signal, amplifiers for amplifying the intensity of a light signal, attenuators for attenuating the intensity of a light signal, modulators for modulating a signal onto a light signal, modulators that convert a light signal to an electrical signal, and vias that provide an optical pathway for a light signal traveling through the device from the bottom side of the device to the top side of the device. Additionally, the device can optionally, include electrical components. For instance, the device can include electrical connections for applying a potential or current to a waveguide and/or for controlling other components on the optical device.

Various embodiments can be described by the following clauses:
1. A cooling assembly, comprising:
   a stiff cold plate; and
   a cooling loop to circulate a cooling fluid throughout the stiff cold plate to dissipate heat from a printed circuit board (PCB).
2. The cooling assembly of clause 1, further comprising one or more connecting elements to removably attach the stiff cold plate to the PCB, the one or more connecting elements comprising at least one of screws, bolts, or fasteners.
3. The cooling assembly of clause 1, wherein the cooling loop covers at least a portion of the stiff cold plate in thermal contact with the PCB.
4. The cooling assembly of clause 1, further comprising an inlet element and an outlet element to circulate the cooling fluid through the cooling loop.
5. The cooling assembly of clause 4, wherein the inlet element and the outlet element are located at opposite ends of the stiff cold plate.
6. The cooling assembly of clause 1, wherein the stiff cold plate is comprised of at least one of aluminum, copper, or composite material.
7. The cooling assembly of clause 1, further comprising one or more connecting elements comprising quick-release elements allowing the stiff cold plate to removably detach from the PCB.
8. The cooling assembly of clause 1, wherein the stiff cold plate has dimensions larger than the PCB and is further to connect to a plurality of additional PCBs.
9. The cooling assembly of clause 1, further comprising one or more temperature sensors to determine a temperature of the PCB.
10. A method for cooling a printed circuit board (PCB), comprising:
   providing a stiff cold plate including one or more connecting elements to connect to one or more corresponding connecting holes of the PCB;
   causing a cooling fluid to circulate through a cooling loop throughout the stiff cold plate; and
   dissipating heat from the PCB via thermal contact with the stiff cold plate.
11. The method of clause 10, wherein the cooling loop covers at least a portion of the stiff cold plate in thermal contact with the PCB.
12. The method of clause 11, wherein the portion of the stiff cold plate in thermal contact with the PCB is proximate to one or more heat-generating elements of the PCB.
13. The method of clause 10, wherein the stiff cold plate further comprises an inlet element and an outlet element to circulate the cooling fluid through the cooling loop.
14. The method of clause 10, wherein the stiff cold plate has dimensions larger than the PCB and is further to connect to a plurality of additional PCBs.
15. The method of clause 10, wherein the stiff cold plate further comprises one or more temperature sensors to determine a temperature of the PCB.
16. The method of clause 10, wherein the one or more connecting elements comprise quick-release elements allowing the stiff cold plate to removably detach from the PCB.
17. An apparatus for cooling a printed circuit board (PCB) comprising a stiff cold plate and a cooling loop to circulate a cooling fluid throughout the stiff cold plate to dissipate heat from the PCB.
18. The apparatus of clause 17, wherein the stiff cold plate further comprises an insulating layer separating the stiff cold plate from the PCB.
19. The apparatus of clause 17, wherein the stiff cold plate further comprises one or more temperature sensors to determine a temperature of the PCB.
20. The apparatus of clause 17, wherein the cooling loop covers at least a portion of the stiff cold plate in thermal contact with the PCB, the portion being proximate to one or more heat-generating elements of the PCB.
21. The apparatus of clause 17, wherein the stiff cold plate comprises one or more connecting elements to connect to one or more corresponding connecting holes of the PCB.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors-for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In the scope of this application, the term arithmetic logic unit, or ALU, is used to refer to any computational logic circuit that processes operands to produce a result. For example, in the present document, the term ALU can refer to a floating point unit, a DSP, a tensor core, a shader core, a coprocessor, or a CPU.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU, DPU, QPU, a plurality of parallel processing units (PPUs). A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. Terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is

1. A cooling assembly, comprising:
a stiff cold plate; and
a cooling loop to circulate a cooling fluid throughout the stiff cold plate to dissipate heat from a printed circuit board (PCB).

2. The cooling assembly of claim 1, further comprising one or more connecting elements to removably attach the stiff cold plate to the PCB, the one or more connecting elements comprising at least one of screws, bolts, or fasteners.

3. The cooling assembly of claim 1, wherein the cooling loop covers at least a portion of the stiff cold plate in thermal contact with the PCB.

4. The cooling assembly of claim 1, further comprising an inlet element and an outlet element to circulate the cooling fluid through the cooling loop.

5. The cooling assembly of claim 4, wherein the inlet element and the outlet element are located at opposite ends of the stiff cold plate.

6. The cooling assembly of claim 1, wherein the stiff cold plate is comprised of at least one of aluminum, copper, or composite material.

7. The cooling assembly of claim 1, further comprising one or more connecting elements comprising quick-release elements allowing the stiff cold plate to removably detach from the PCB.

8. The cooling assembly of claim 1, wherein the stiff cold plate has dimensions larger than the PCB and is further to connect to a plurality of additional PCBs.

9. The cooling assembly of claim 1, further comprising one or more temperature sensors to determine a temperature of the PCB.

10. A method for cooling a printed circuit board (PCB), comprising:
providing a stiff cold plate including one or more connecting elements to connect to one or more corresponding connecting holes of the PCB;
causing a cooling fluid to circulate through a cooling loop throughout the stiff cold plate; and
dissipating heat from the PCB via thermal contact with the stiff cold plate.

11. The method of claim 10, wherein the cooling loop covers at least a portion of the stiff cold plate in thermal contact with the PCB.

12. The method of claim 11, wherein the portion of the stiff cold plate in thermal contact with the PCB is proximate to one or more heat-generating elements of the PCB.

13. The method of claim 10, wherein the stiff cold plate further comprises an inlet element and an outlet element to circulate the cooling fluid through the cooling loop.

14. The method of claim 10, wherein the stiff cold plate has dimensions larger than the PCB and is further to connect to a plurality of additional PCBs.

15. The method of claim 10, wherein the stiff cold plate further comprises one or more temperature sensors to determine a temperature of the PCB.

16. The method of claim 10, wherein the one or more connecting elements comprise quick-release elements allowing the stiff cold plate to removably detach from the PCB.

17. An apparatus for cooling a printed circuit board (PCB) comprising a stiff cold plate and a cooling loop to circulate a cooling fluid throughout the stiff cold plate to dissipate heat from the PCB.

18. The apparatus of claim 17, wherein the stiff cold plate further comprises an insulating layer separating the stiff cold plate from the PCB.

19. The apparatus of claim 17, wherein the stiff cold plate further comprises one or more temperature sensors to determine a temperature of the PCB.

20. The apparatus of claim 17, wherein the cooling loop covers at least a portion of the stiff cold plate in thermal contact with the PCB, the portion being proximate to one or more heat-generating elements of the PCB.

21. The apparatus of claim 17, wherein the stiff cold plate comprises one or more connecting elements to connect to one or more corresponding connecting holes of the PCB.
